(19) United States
(12) Patent Application Publication
(10) Pub. No.: US 2026/0339769 A1
(43) Pub. Date: Oct. 29, 2026

(54) Tree-Based Small Dictionaries For Improving Diagnosis Performance

(71) Applicant: Siemens Industry Software Inc., Plano, TX (US)

(72) Inventors: Wu-Tung Cheng, Seattle, WA (US); Szczepan Urban, Gowarzewo (PL); Manish Sharma, Wilsonville, OR (US); Jakub Janicki, Poznan (PL)

(73) Assignee: Siemens Industry Software Inc., Plano, FL (US)

(21) Appl. No.: 19/659,593

(22) Filed: Apr. 27, 2026

Related U.S. Application Data
(60) Provisional application No. 63/796,109, filed on Apr. 28, 2025.

(51) Int. Cl. G06F 11/07

(52) U.S. Cl. CPC G06F 11/079; G06F 11/0721

(57) ABSTRACT

Various aspects of the present disclosed technology relate to techniques of small dictionary-assisted effect-cause diagnosis of circuit test response data. A fault partition node system is created for a circuit design based on fault simulation of the plurality of faults for each of the plurality of test patterns. Each fault partition node is associated with a respective equivalent fault group. For each equivalent fault group, a set of failing signatures is computed. The sets of failing signatures, the equivalent fault groups, and parent-child relationship information of the equivalent fault groups are stored as a fault dictionary. Effect-cause diagnosis is performed based on a set of initial fault suspects determined using the fault dictionary together with test response bits obtained from a failing circuit fabricated according to the circuit design.

### FIELD OF THE DISCLOSED TECHNOLOGY

The present disclosed technology relates to the field of circuit test and diagnosis. Various implementations of the disclosed technology may be particularly useful for improving effect-cause fault diagnosis performance.

### BACKGROUND OF THE DISCLOSED TECHNOLOGY

Modern integrated circuits are complex. At leading technology nodes, feature sizes have shrunk to just a few nanometers. Non-planar, or "three-dimensional," transistors — such as FinFET and GAA (gate-all-around) — are increasingly used to achieve higher performance with lower power consumption. These non-planar transistors and their interconnections have more complicated structures with additional layers, thereby requiring more process steps. More process steps combined with smaller feature sizes can introduce a greater number of potential defect root causes. For these integrated circuits to be commercially viable, manufacturing yield must reach and remain above a certain threshold. Therefore, accurately identifying yield-limiting root causes has become critically important. In the past, bitmapping of static random-access memories (SRAMs) has been employed as a "yield learning vehicle." At leading technology nodes, however, the ability to manufacture these regular structures does not guarantee that a product with irregular structures can be successfully manufactured.

Software-based diagnosis of scan test failures has proven to be of enormous value for yield learning. Scan testing is commonly used in the manufacturing process to verify that integrated circuits have been fabricated correctly. Diagnosis uses failure data from scan testing along with circuit design information to determine the most likely defect locations and mechanisms in failing circuits (dies). Diagnosis results can guide physical failure analysis (PFA) to focus on a much smaller area within a failing circuit, leading to higher PFA success rates with reduced turnaround time and cost. Based on the yield loss mechanisms identified through PFA, circuit design or manufacturing processes can be adjusted to improve manufacturing yields.

Defect diagnosis methods can be classified into two types: Cause-Effect and Effect-Cause. Cause-effect diagnosis, also referred to as dictionary-based diagnosis, pre-computes and stores the faulty responses of modeled faults in a dictionary. During diagnosis, the observed failure responses are compared against the pre-computed failure responses stored in the dictionary. The faults whose pre-computed failure responses most closely match the observed failure responses are selected as the final fault candidates. Because dictionary-based diagnosis does not perform fault simulations during the diagnosis phase, it operates at very high speed. However, dictionary-based diagnosis requires a very large amount of memory to store the pre-computed failure responses. Although several techniques have been proposed to reduce dictionary size, the resulting reduced dictionaries remain too large for current designs containing hundreds of millions of gates. Furthermore, certain size-reduction approaches — such as pass/fail dictionaries — may sacrifice diagnosis accuracy due to information loss.

Rather than simulating all faults upfront, effect-cause diagnosis identifies initial suspects by backward path tracing from failing outputs and then simulates only those initial suspects to determine the fault candidates. Compared to cause-effect diagnosis, effect-cause diagnosis can typically achieve higher accuracy and better resolution while requiring less memory to store pre-computed faulty responses. However, the runtime of effect-cause diagnosis is longer due to the larger number of fault simulations performed during the process. While several methods have been proposed to reduce the runtime of effect-cause diagnosis by leveraging small dictionaries, these dictionaries remain too large for large industrial designs with tens of thousands of test patterns.

### BRIEF SUMMARY OF THE DISCLOSED TECHNOLOGY

Various aspects of the present disclosed technology relate to techniques of small dictionary-assisted effect-cause diagnosis of circuit test response data. In one aspect, there is a method comprising: receiving a circuit design, a plurality of faults, and a plurality of test patterns; creating a fault partition node system for the circuit design based on fault simulation of the plurality of faults for each of the plurality of test patterns, each fault partition node being associated with a respective equivalent fault group; computing, for each equivalent fault group in the fault partition node system, a respective set of failing signatures, each failing signature in the respective set of failing signatures being derived from test response bits of a respective failing test pattern in the plurality of test patterns that fails for the each equivalent fault group, the respective set of failing signatures comprising failing signatures for failing test patterns spanning from a partition clock cycle of a fault partition node associated with the each equivalent fault group to a last failing clock cycle of the each equivalent fault group; and storing, as a fault dictionary, the sets of failing signatures, the equivalent fault groups, and parent-child relationship information of the equivalent fault groups.

The method may further comprise: searching in the fault dictionary for failing signatures that match failing signatures derived from test response bits obtained from a failing circuit fabricated according to the circuit design to determine a set of initial fault suspects; performing fault simulation on the set of initial suspects using failing test patterns in the plurality of test patterns that correspond to the initial fault suspects to determine a set of initial fault candidates; performing a minimum set coverage analysis on the set of initial fault candidates to determine a set of intermediate fault candidates; and performing fault simulation on the set of intermediate fault candidates using passing test patterns in the plurality of test patterns to determine a set of final ranked fault candidates.

The failing signatures may be computed only for test patterns having no more than a predetermined number of failing bits. The method may further comprise: performing backward path tracing for test patterns having more than the predetermined number of failing bits to determine a first set of initial fault suspects, the backward path tracing being based on test response bits obtained from a failing circuit fabricated according to the circuit design; searching in the fault dictionary for failing signatures that match failing signatures derived from test response bits obtained from the failing circuit for test patterns having no more than the predetermined number of failing bits to determine a second set of initial fault suspects; performing fault simulation on the first and second sets of initial suspects using failing test patterns in the plurality of test patterns that correspond to the first and second sets of initial fault suspects to determine a set of initial fault candidates; performing a minimum set coverage analysis on the set of initial fault candidates to determine a set of intermediate fault candidates; and performing fault simulation on the set of intermediate fault candidates using passing test patterns in the plurality of test patterns to determine a set of final ranked fault candidates.

The fault simulation for creating a fault partition node system may be performed for each of the plurality of test patterns in a sequence to determine test response bits from each of one or more test response output channels of the circuit design, the sequence being the same as a sequence in which the plurality of test patterns would be used to test a circuit fabricated according to the circuit design, the test response bits comprising passing bits and failing bits, and wherein the creating a fault partition node system is based on the test response bits determined by the fault simulation, the fault partition node system comprising fault partition nodes and equivalent fault groups, each of the fault partition nodes being associated with one of the equivalent fault groups, each of the equivalent fault groups comprising one or more faults in the plurality of faults, the generating comprising: creating (N 1) new fault partition nodes for an existing fault partition node if an existing equivalent fault group associated with the existing fault partition node is separated into N new equivalent fault groups based on one or more test response bits at an observation clock cycle, associating the N new equivalent fault groups with the (N 1) new fault partition nodes and the existing fault partition node, respectively, and removing the association of the existing equivalent fault group with the existing fault partition node.

The fault partition node system may be created for each of the one or more test response output channels, a number of fault partition node systems generated being equal to a number of the one or more test response output channels, wherein N = 2 and the creating comprising: creating a new fault partition node for an existing fault partition node if an existing equivalent fault group associated with the existing fault partition node is separated into two new equivalent fault groups based on a failing bit at an observation clock cycle; associating the two new equivalent fault groups with the new fault partition node and the existing fault partition node, respectively; and removing the association of existing equivalent fault group with the existing fault partition node. One of the two new equivalent fault groups having the failing bit may be associated with the new fault partition node.

In another aspect, there is one or more computer-readable media storing computer-executable instructions for causing one or more processors to perform the above method.

Certain inventive aspects are set out in the accompanying independent and dependent claims. Features from the dependent claims may be combined with features of the independent claims and with features of other dependent claims as appropriate and not merely as explicitly set out in the claims.

Certain objects and advantages of various inventive aspects have been described herein above. Of course, it is to be understood that not necessarily all such objects or advantages may be achieved in accordance with any particular embodiment of the disclosed technology. Thus, for example, those skilled in the art will recognize that the disclosed technology may be embodied or carried out in a manner that achieves or optimizes one advantage or group of advantages as taught herein without necessarily achieving other objects or advantages as may be taught or suggested herein.

### BRIEF DESCRIPTION OF THE DRAWINGS

FIG. 1 illustrates an example of a computing device that may be used to implement various embodiments of the disclosed technology.

FIG. 2 illustrates an example fault dictionary generation tool and an example effect-cause diagnosis tool that may be implemented according to various embodiments of the disclosed technology.

FIG. 3 illustrates a flowchart showing a process of fault dictionary generation for diagnosis that may be implemented according to various examples of the disclosed technology.

FIG. 4A illustrates a flowchart showing a process of fault dictionary-assisted effect-cause diagnosis that may be implemented independently according to various examples of the disclosed technology.

FIG. 4B illustrates a flowchart showing another process of fault dictionary-assisted effect-cause diagnosis that may be implemented independently according to various examples of the disclosed technology.

FIG. 5 illustrates a flowchart showing a process of fault partition node system generation that may be implemented according to various examples of the disclosed technology.

FIG. 6 illustrates a flowchart showing an example process for creating new fault partition nodes for an observation-clock-cycle-based fault partition node system for a circuit design that may be implemented according to various examples of the disclosed technology.

FIG. 7 uses a diagram as an example to illustrate a process for creating new fault partition nodes for an observation-clock-cycle-based fault partition node system for a circuit design that may be implemented according to various examples of the disclosed technology.

FIG. 8 uses a diagram as an example to illustrate a process for creating new fault partition nodes for an observation-clock-cycle-based fault partition node system for one test response output channel that may be implemented according to various examples of the disclosed technology.

### DETAILED DESCRIPTION OF THE DISCLOSED TECHNOLOGY

### General Considerations

Various aspects of the present disclosed technology relate to techniques of small dictionary-assisted effect-cause diagnosis of circuit test response data. In the following description, numerous details are set forth for the purpose of explanation. However, one of ordinary skill in the art will realize that the disclosed technology may be practiced without the use of these specific details. In other instances, well-known features have not been described in detail to avoid obscuring the present disclosed technology.

Some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. Moreover, for the sake of simplicity, the disclosed flow charts and block diagrams typically do not show the various ways in which particular methods can be used in conjunction with other methods.

The detailed description sometimes uses terms like “perform”, “generate,” “compute,” and “create” to describe the disclosed methods/systems. Such terms are high-level descriptions of the actual operations that are performed. The actual operations that correspond to these terms will vary depending on the particular implementation and are readily discernible by one of ordinary skill in the art.

As used in this disclosure, the singular forms “a,” “an,” and “the” include the plural forms unless the context clearly dictates otherwise. Additionally, the term “includes” means “comprises.” Moreover, unless the context dictates otherwise, the term “coupled” means electrically or electromagnetically connected or linked and includes both direct connections or direct links and indirect connections or indirect links through one or more intermediate elements not affecting the intended operation of the circuit.

Additionally, as used herein, the term “design” is intended to encompass data describing an entire integrated circuit device. This term also is intended to encompass a smaller group of data describing one or more components of an entire device such as a portion of an integrated circuit device, nevertheless.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one microdevice, such as data to be used to form multiple microdevices on a single wafer.

### Design For Test, Test Pattern Generation, And Testing

The reduction in feature size increases the probability that a manufacture defect in an integrated circuit will result in a faulty chip. A very small defect can result in a faulty transistor or interconnecting wire. Even a single faulty transistor or wire can cause the entire chip to function improperly. Manufacture defects are unavoidable nonetheless, no matter whether the manufacturing process is at the prototype stage or the high-volume manufacturing stage. It is thus necessary to test chips during the manufacturing process. Diagnosing faulty chips is also needed to ramp up and to maintain the manufacturing yield.

Testing typically includes applying a set of test stimuli (test patterns) to the circuit-under-test and then analyzing responses generated by the circuit-under-test. Functional testing attempts to validate that the circuit-under-test operates according to its functional specification while structural testing tries to ascertain that the circuit-under-test has been assembled correctly from some low-level building blocks as specified in a structural netlist and that these low-level building blocks and their wiring connections have been manufactured without defect. For structural testing, it is assumed that if functional verification has shown the correctness of the netlist and structural testing has confirmed the correct assembly of the structural circuit elements, then the circuit should function correctly. Structural testing has been widely adopted at least in part because it enables the test (test pattern) generation to focus on testing a limited number of relatively simple circuit elements rather than having to deal with an exponentially exploding multiplicity of functional states and state transitions.

To make it easier to develop and apply test patterns, certain testability features are added to circuit designs, which is referred to as design for test or design for testability (DFT). Scan testing is the most common DFT method. In a basic scan testing scheme, all or most of internal sequential state elements (latches, flip-flops, et al.) in a circuit design are made controllable and observable via a serial interface. These functional state elements are usually replaced with dual-purpose state elements called scan cells. Scan cells are connected together to form scan chains – serial shift registers for shifting in test patterns and shifting out test responses. A scan cell can operate as originally intended for functional purposes (functional/mission mode) and as a unit in a scan chain for scan testing (scan mode). A widely used type of scan cell includes an edge-trigged flip-flop with two-way multiplexer for the data input. The two-way multiplexer is typically controlled by a single control signal called scan_enable, which selects the input signal for a scan cell from either a scan signal input port or a system signal input port. The scan signal input port is typically connected to an output of another scan cell while the system signal input port is connected to the functional logic. Scan cells can serve as both a control point and an observation point. Control points can be used to set certain logic values at some locations of the circuit-under-test, exciting (activating) a fault and propagating the incorrect value to an observation point. Scan testing allows the test equipment to access gates deeply embedded through the primary inputs/outputs and/or some physical test points and can remove the need for complicated state transition sequences when trying to control or observe what is happening at some internal circuit element.

In a typical scan test, a series of known values (test stimuli or test pattern) are shifted-in (or loaded into) scan cells through their sequential inputs. The shifting-in occurs by placing the integrated circuit in a special mode, known as shift mode, and then applying a series of clock pulses, called “shift pulses” or “shift clock pulses.” Each shift clock pulse pushes a bit of test stimuli into a scan cell in each of the scan chains. This continues until all scan cells in the scan chains are filled with test pattern bits. Then, one or more clock pulses, called “capture pulses” or “capture clock pulses,” are applied to the circuit as they would be in normal operation. This is referred to as capture mode. After the test pattern bits are injected into the circuit, the results of the test (test responses) are “captured” and stored in the scan cells. The circuit then returns to shift mode, and with each additional clock pulse, a bit of the test responses is pushed or shifted out as each bit of new test pattern is pushed or shifted in. The shifted-out test responses are then compared with expected results to determine and locate any errors. Shift mode and capture mode together may be called as test mode.

Test patterns for scan testing are typically generated through an automatic test pattern generation (ATPG) process. ATPG usually focuses on a set of faults derived from a gate-level fault model. A defect is a flaw or physical imperfection caused in a device during the manufacturing process. A fault model (or briefly a fault) is a description of how a defect alters design behavior. For a given target fault, ATPG comprises two phases: fault activation and fault propagation. Fault activation establishes a signal value at the fault site opposite that produced by the fault (e.g., for a stuck-at-0 fault, the fault activation process will try to establish a logic '1' at that site). Fault propagation propagates the fault effect (e.g., stuck at 0) forward by sensitizing a path from a fault site to a scan cell or a primary output. A fault at a site is said to be detected by a test pattern if a test response value captured by a scan cell or a primary output is different than the expected value. The objective of ATPG is to find a test pattern that, when applied to the circuit, enables testers to distinguish between the correct circuit behavior and the faulty circuit behavior caused by one or more particular faults. Effectiveness of ATPG is measured by the fault coverage achieved for the fault model and the number of generated vectors (test pattern counts), which should be directly proportional to test application time. Here, the fault coverage is defined as a ratio of the number of detected faults vs. the total number of faults.

A popular fault model used in practice is the single stuck-at fault model. In this model, one of the signal lines in a circuit is assumed to be stuck at a fixed logic value, regardless of what inputs are supplied to the circuit. The stuck-at fault model is a logical fault model because no delay information is associated with the fault definition. Delay faults cause errors in the functioning of a circuit based on its timing. They are caused by the finite rise and fall time periods of the signals in the gates, as well as the propagation delay of interconnects between the gates. Transition faults are used for their simplicity in modeling spot defects that affect delays at inputs or outputs of gates. Under scan-based tests, the transition faults are associated with an extra delay that is large enough to cause the delay of any path through the fault site to exceed the clock period. Cell internal fault models can be derived using transistor-level circuit simulations (analog simulations). This approach can pinpoint the defect location within a cell for various cell internal defects.

During the circuit design and manufacturing process, a manufacturing test screens out chips (dies) containing defects. The test itself, however, does not identify the reason for the unacceptable low or fluctuating yield that may be observed. Physical failure analysis (PFA) can inspect the faulty chip to locate the defect location(s) and to discover the root cause. The process usually includes etching away certain layers and then imaging the silicon surface by scanning electronic microscopy or focused ion beam systems. This PFA process is laborious and time consuming. To facilitate the PFA process, diagnosis (also referred to as scan diagnosis) is often employed to narrow down possible locations of the defect(s) based on analyzing the fail log (fail file, failure file). The fail log typically contains information about when (e.g., tester cycle), where (e.g., at what tester channel), and how (e.g., at what logic value) the test failed and which test patterns generate expected test responses. The layout information of the circuit design may also be employed to further reduce the number of defect suspects.

Diagnosis includes logic diagnosis (sometimes referred to as scan diagnosis) and chain diagnosis. Logic diagnosis may employ a fault dictionary or directly examine the syndrome (i.e., the effect) of the failing chip to determine likely defect locations (defect suspects). The latter approach may include structural pruning (back tracing), fault injection and evaluation (fault simulation for both failing and passing test patterns).

Chain diagnosis determines scan cells that are likely to be defective. Scan elements and related clocking circuitry can take up about 30% of silicon area of an IC chip. It has been reported that scan chain failures account for almost 50% of chip failure in some cases. Chain diagnosis is thus important to guide physical failure analysis and yield learning process. In a chain diagnosis process, two types of test patterns may be used. The first type is called chain patterns. A chain pattern is a pattern used in a process comprising shift-in and shift-out without pulsing capture clocks. The other type is often referred to as scan patterns. A scan pattern is a pattern used in a process comprising shift-in, one or multiple capture clock cycles, and shift-out, and the scan patterns include patterns generated by ATPG for testing system logic, special chain diagnostic patterns generated only for scan chain diagnosis purpose and some special functional patterns. Chain patterns can be used to test the integrity of scan chains and/or determine fault models associated with faulty scan chains while scan patterns can be used to inject certain values to some scan cells for locating defective scan cells.

The quality of diagnosis can be measured by diagnostic resolution (the number of the real defects vs. the number of the defect suspects). Diagnostic resolution is linked not only to the algorithm used for diagnosis but also to the test patterns used for the manufacturing test (manufacturing test patterns). The quality of diagnosis can also be measured by diagnosis coverage. Diagnosis coverage may be determined in several ways. A simple way is to divide the number of equivalent fault groups by the number of faults. Faults in an equivalent fault group cannot be separated or distinguished under a certain condition by a diagnosis technique. To enhance the quality of diagnosis, a diagnostic test pattern generation process may be employed. This process generates test patterns that can increase the number of equivalent fault groups or reduce the average number of faults in the equivalent fault groups.

Test application in chip manufacturing test is normally performed by automatic test equipment (ATE) (a type of testers). Scan-based tests consume significant amounts of storage and test time on ATE. The data volume increases with the number of logic gates on the chip and the same holds for the number of scan cells. Yet, practical considerations and ATE specifications often limit both the number of pins available for scan in/out and the maximum scan frequency. It is highly desirable to reduce the amount of test data that need to be loaded onto ATE and ultimately to the circuit under test. Fortunately, test patterns are compressible mainly because only 1% to 5% of test pattern bits are typically specified bits (care bits) while the rest are unspecified bits (don't-care bits). Unspecified bits can take on any values with no impact on the fault coverage. Test compression may also take advantage of the fact that test cubes tend to be highly correlated. A test cube is a deterministic test pattern in which the don't-care bits are not filled by ATPG. The correlation exists because faults are structurally related in the circuit.

Various test compression techniques have been developed. In general, additional on-chip hardware before and after scan chains is inserted. The hardware (decompressor) added before scan chains is configured to decompress test stimulus coming from ATE, while the hardware (compactor) added after scan chains is configured to compact test responses captured by the scan chains. The decompressor expands the data from n tester channels to fill greater than n scan chains. The increase in the number of scan chains shortens each scan chain and thus reduces the number of clock cycles needed to shift in each test pattern. Thus, test compression can not only reduce the amount of data stored on the tester but also reduce the test time for a given test data bandwidth.

### Illustrative Operating Environment

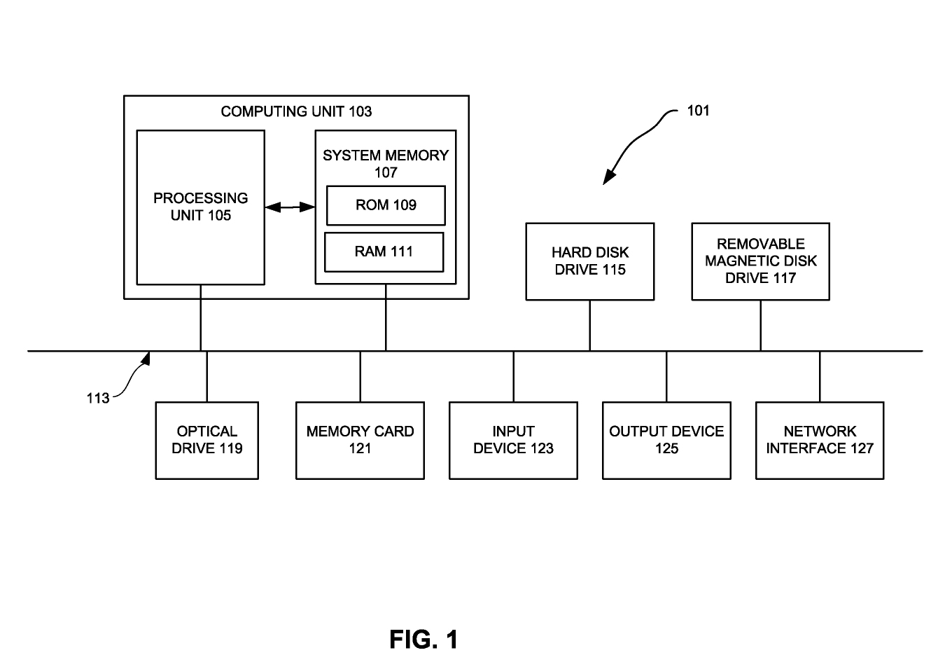

Various examples of the disclosed technology may be implemented through the execution of software instructions by a computing device, such as a programmable computer. Accordingly, FIG. 1 shows an illustrative example of a computing device 101. As seen in this figure, the computing device 101 includes a computing unit 103 with a processing unit 105 and a system memory 107. The processing unit 105 may be any type of programmable electronic device for executing software instructions, but it will conventionally be a microprocessor. The system memory 107 may include both a read-only memory (ROM) 109 and a random access memory (RAM) 111. As will be appreciated by those of ordinary skill in the art, both the read-only memory (ROM) 109 and the random access memory (RAM) 111 may store software instructions for execution by the processing unit 105.

The processing unit 105 and the system memory 107 are connected, either directly or indirectly, through a bus 113 or alternate communication structure, to one or more peripheral devices. For example, the processing unit 105 or the system memory 107 may be directly or indirectly connected to one or more additional memory storage devices, such as a “hard” magnetic disk drive 115, a removable magnetic disk drive 117, an optical disk drive 119, or a flash memory card 121. The processing unit 105 and the system memory 107 also may be directly or indirectly connected to one or more input devices 123 and one or more output devices 125. The input devices 123 may include, for example, a keyboard, a pointing device (such as a mouse, touchpad, stylus, trackball, or joystick), a scanner, a camera, and a microphone. The output devices 125 may include, for example, a monitor display, a printer and speakers. With various examples of the computer 101, one or more of the peripheral devices 115-125 may be internally housed with the computing unit 103. Alternately, one or more of the peripheral devices 115-125 may be external to the housing for the computing unit 103 and connected to the bus 113 through, for example, a Universal Serial Bus (USB) connection.

With some implementations, the computing unit 103 may be directly or indirectly connected to one or more network interfaces 127 for communicating with other devices making up a network. The network interface 127 translates data and control signals from the computing unit 103 into network messages according to one or more communication protocols, such as the transmission control protocol (TCP) and the Internet protocol (IP). Also, the interface 127 may employ any suitable connection agent (or combination of agents) for connecting to a network, including, for example, a wireless transceiver, a modem, or an Ethernet connection. Such network interfaces and protocols are well known in the art, and thus will not be discussed here in more detail.

It should be appreciated that the computer 101 is illustrated as an example only, and it is not intended to be limiting. Various embodiments of the disclosed technology may be implemented using one or more computing devices that include the components of the computer 101 illustrated in FIG. 1, which include only a subset of the components illustrated in FIG. 1, or which include an alternate combination of components, including components that are not shown in FIG. 1. For example, various embodiments of the disclosed technology may be implemented using a multi-processor computer, a plurality of single and/or multiprocessor computers arranged into a network, or some combination of both.

### Fault Dictionary Generation And Effect-Cause Diagnosis Tools

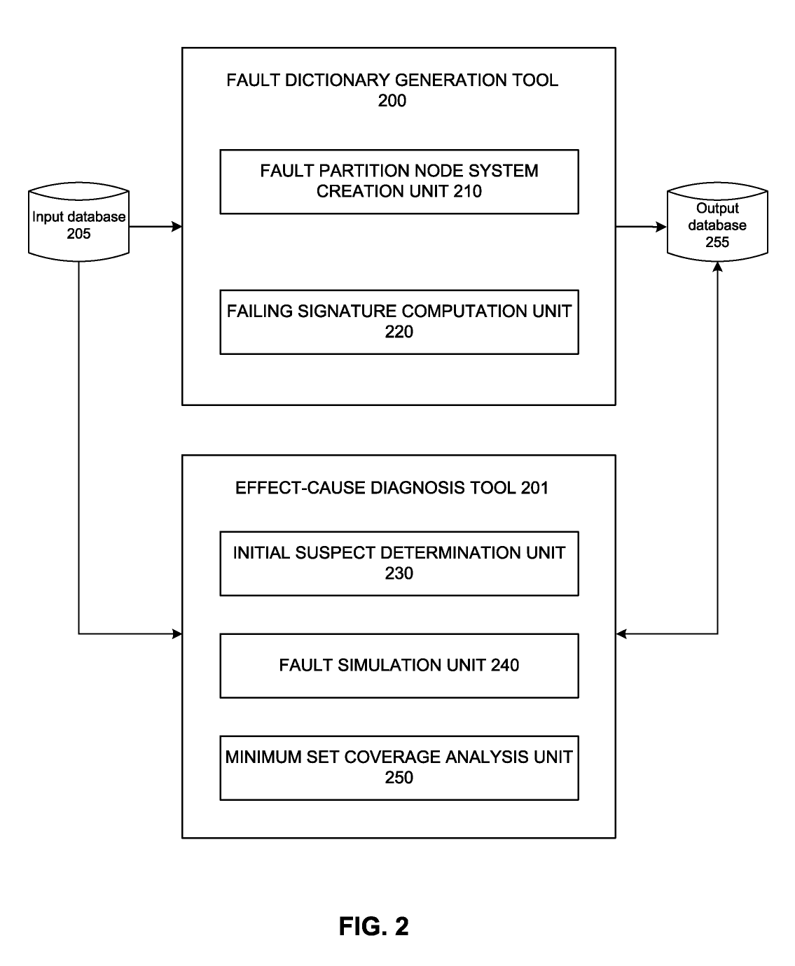

FIG. 2 illustrates an example fault dictionary generation tool 200 and an example effect-cause diagnosis tool 201 that may be implemented according to various embodiments of the disclosed technology. As seen in this figure, the fault dictionary generation tool 200 includes a fault partition node system creation unit 210 and a failing signature computation unit 220, and the effect-cause diagnosis tool 201 includes an initial suspect determination unit 230, a fault simulation unit 240, and a minimum set coverage analysis unit 250. Various implementations of the fault dictionary generation tool 200 and the effect-cause diagnosis tool 201 may include cooperation between the two tools and cooperate with (or incorporate) one or more of an input database 205 and an output database 255.

As will be discussed in more detail below, the fault dictionary generation tool 200 can receive, from the input database 205, a circuit design, a plurality of faults, and a plurality of test patterns. The fault partition node system creation unit 210 can create a fault partition node system for the circuit design based on fault simulation for each of the plurality of test patterns. The failing signature computation unit 220 can compute for each equivalent fault group of the fault partition node system, a respective set of failing signatures. Each failing signature in the respective set of failing signatures is derived from test response bits of a respective failing test pattern in the plurality of test patterns that fails for the each equivalent fault group. The respective set of failing signatures comprises failing signatures for failing test patterns spanning from a partition clock cycle of a fault partition node associated with the each equivalent fault group to a last failing clock cycle of the each equivalent fault group. The fault dictionary generation tool 200 can then store, as a fault dictionary, the sets of failing signatures, the equivalent fault groups, and parent-child relationship information of the equivalent fault groups in the output database 255.

The effect-cause diagnosis tool 201 can receive the circuit design, the plurality of faults, the plurality of test patterns, the fault dictionary generated by the fault dictionary generation tool 200, and test response bits obtained from a failing circuit fabricated according to the circuit design. The effect-cause diagnosis tool 201 can compute fault signatures for test response failing bits following the same signature derivation method used by the failing signature computation unit 220. The initial suspect determination unit 230 can search in the fault dictionary for failing signatures that match these failing signatures for the failing circuit to determine a set of initial fault suspects. The fault simulation unit 240 can perform fault simulation on the set of initial suspects using failing test patterns in the plurality of test patterns that correspond to the initial fault suspects to determine a set of initial fault candidates. The minimum set coverage analysis unit 250 can perform a minimum set coverage analysis on the set of initial fault candidates to determine a set of intermediate fault candidates. Then the fault simulation unit 240 can perform fault simulation on the set of intermediate fault candidates using passing test patterns in the plurality of test patterns to determine a set of final ranked fault candidates.

According to some embodiments of the disclosed technology, the failing signature computation unit 220 may compute the failing signatures only for test patterns having no more than a predetermined number of failing bits. The initial suspect determination unit 230 can perform backward path tracing for test patterns having more than the predetermined number of failing bits to determine a first set of initial fault suspects, and search in the fault dictionary for failing signatures that match failing signatures derived from test response bits obtained from the failing circuit for test patterns having no more than the predetermined number of failing bits to determine a second set of initial fault suspects. Then the fault simulation unit 240 can perform fault simulation on the first and second set of initial suspects using failing test patterns in the plurality of test patterns that correspond to the initial fault suspects to determine a set of initial fault candidates.

As previously noted, various examples of the disclosed technology may be implemented by one or more computing systems, such as the computing system illustrated in FIG. 1. Accordingly, one or more of the fault partition node system creation unit 210, the failing signature computation unit 220, the initial suspect determination unit 230, the fault simulation unit 240, and the minimum set coverage analysis unit 250 may be implemented by executing programming instructions on one or more processors in one or more computing systems, such as the computing system illustrated in FIG. 1. Correspondingly, some other embodiments of the disclosed technology may be implemented by software instructions, stored on a non-transitory computer-readable medium, for instructing one or more programmable computers/computer systems to perform the functions of one or more of the fault partition node system creation unit 210, the failing signature computation unit 220, the initial suspect determination unit 230, the fault simulation unit 240, and the minimum set coverage analysis unit 250. As used herein, the term “non-transitory computer-readable medium” refers to computer-readable medium that are capable of storing data for future retrieval, and not propagating electro-magnetic waves. The non-transitory computer-readable medium may be, for example, a magnetic storage device, an optical storage device, or a solid state storage device.

It also should be appreciated that, while the fault partition node system creation unit 210, the failing signature computation unit 220, the initial suspect determination unit 230, the fault simulation unit 240, and the minimum set coverage analysis unit 250 are shown as separate units in FIG. 1, a single computer (or a single processor within a master computer) or a single computer system may be used to implement some or all of these units at different times, or components of these units at different times.

With various examples of the disclosed technology, the input database 205 and the output database 255 may be implemented using any suitable computer readable storage device. That is, either of the input database 205 and the output database 255 may be implemented using any combination of computer readable storage devices including, for example, microcircuit memory devices such as read-write memory (RAM), read-only memory (ROM), electronically erasable and programmable read-only memory (EEPROM) or flash memory microcircuit devices, CD-ROM disks, digital video disks (DVD), or other optical storage devices. The computer readable storage devices may also include magnetic cassettes, magnetic tapes, magnetic disks or other magnetic storage devices, holographic storage devices, or any other non-transitory storage medium that can be used to store desired information. While the input database 205 and the output database 255 are shown as separate units in FIG. 2, a single data storage medium may be used to implement some or all of these databases.

### Fault Dictionary Generation For Diagnosis

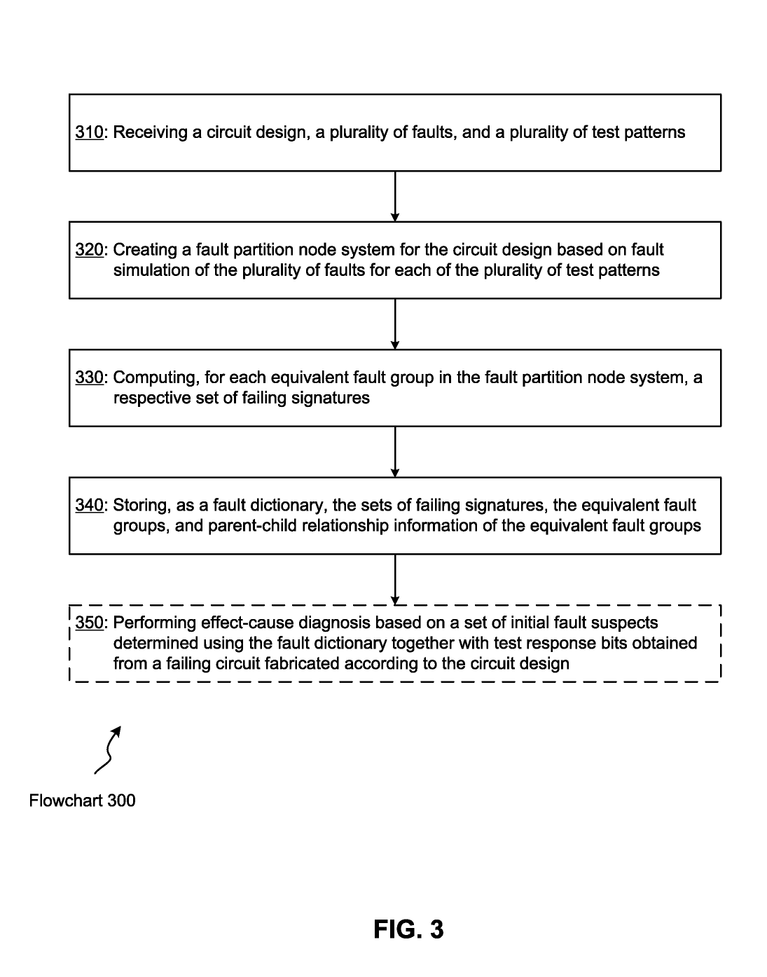

FIG. 3 illustrates a flowchart 300 showing a process of fault dictionary generation for diagnosis that may be implemented according to various examples of the disclosed technology. For ease of understanding, methods of fault dictionary generation for diagnosis that may be employed according to various embodiments of the disclosed technology will be described with reference to the fault dictionary generation tool 200 in FIG. 2 and the flow chart 300 illustrated in FIG. 3. It should be appreciated, however, that alternate implementations of a fault dictionary generation tool may be used to perform the methods of fault dictionary generation for diagnosis illustrated by the flow chart 300 according to various embodiments of the disclosed technology. Likewise, the fault dictionary generation tool 200 may be employed to perform other methods of fault dictionary generation for diagnosis according to various embodiments of the disclosed technology.

In operation 310 of the flow chart 300, the fault dictionary generation tool 200 receives, from the input database 205, a circuit design, a plurality of faults, and a plurality of test patterns. The plurality of test patterns may be the same ones used for test chips during the manufacturing process.

In operation 320, the fault partition node system creation unit 210 creates a fault partition node system for the circuit design. The fault partition node system has a tree-like structure and is constructed based on fault simulation of the plurality of faults for each of the plurality of test patterns. Fault simulation involves injecting a fault into the circuit design, applying a test pattern to the fault-injected circuit design, and deriving the resulting test response bits. The fault partition node system creation unit 210 may employ the same fault simulation method used by the fault simulation unit 240 in the effect-cause diagnosis tool 201. The fault partition node system creation unit 210 performs fault simulation in the same sequence in which the plurality of test patterns would be used to test a circuit fabricated according to the circuit design.

Each fault partition node is associated with a respective equivalent fault group and a respective observation clock cycle at which a respective fault partition occurs. Faults in an equivalent fault group are faults that cannot be distinguished under a certain condition. The certain condition can be related to the test patterns used. Equivalent fault groups can be changed with the condition. When additional test patterns are used, for example, some or all of the existing equivalent fault groups may be divided into new equivalent fault groups, resulting in more equivalent fault groups. On the other hand, when some of the test patterns are removed from being considered, some or all of the existing equivalent fault groups may be merged into new equivalent fault groups, resulting in fewer equivalent fault groups. The creation of the fault partition node system will be discussed in detail later.

In operation 330, the failing signature computation unit 220 computes, for each equivalent fault group in the fault partition node system, a respective set of failing signatures. Each failing signature in the respective set of failing signatures is derived from test response bits of a respective failing test pattern in the plurality of test patterns that fails for the equivalent fault group in question. The respective set of failing signatures can comprise failing signatures for failing test patterns spanning from a partition clock cycle of the fault partition node associated with the equivalent fault group in question to a last failing clock cycle of that group.

The failing signature computation unit 220 can use various methods to compute failing signatures. For example, a Multiple-Input Signature Register (MISR) may be used: test response bits for a failing test pattern may be injected into a 32-bit MISR to produce a 32-bit failing signature like how an MISR is used to compact test response bits in some circuit testing architectures.

In operation 340, the fault dictionary generation tool 200 stores, as a fault dictionary, the sets of failing signatures, the equivalent fault groups, and their parent-child relationship information in the output database 255.

In the fault partition node system, the number of fault partition nodes – the number of equivalent fault groups – is typically smaller than the number of the plurality of faults since many equivalent fault groups contain more than one fault. Additionally, each equivalent fault group is associated with a set of failing signatures covering only a specific range of test patterns. As a result, the fault dictionary produced by the fault dictionary generation tool 200 is significantly more compact than conventional fault dictionaries. Furthermore, the number of failing signatures in each set scales linearly with the number of associated test patterns, and the number of test patterns associated with a fault partition node in the fault partition node system decreases progressively from the root to the leaves. For larger circuit designs, there are more fault partition node levels and more fault partition nodes at lower levels, meaning the relative reduction in dictionary size is proportionally greater for larger designs than for smaller ones.

To further reduce fault dictionary size, the failing signature computation unit 220 may compute failing signatures only for test patterns having no more than a predetermined number of failing bits according to some embodiments of the disclosed technology. This approach offers a flexible tradeoff between memory usage and diagnostic performance. When memory is limited, a small value for the predetermined number of failing bits can be used to accelerate diagnosis with minimal memory overhead. When more memory is available, a larger dictionary produced with a higher predetermined number of failing bits can deliver a better performance speedup built with a higher threshold can deliver greater performance improvements.

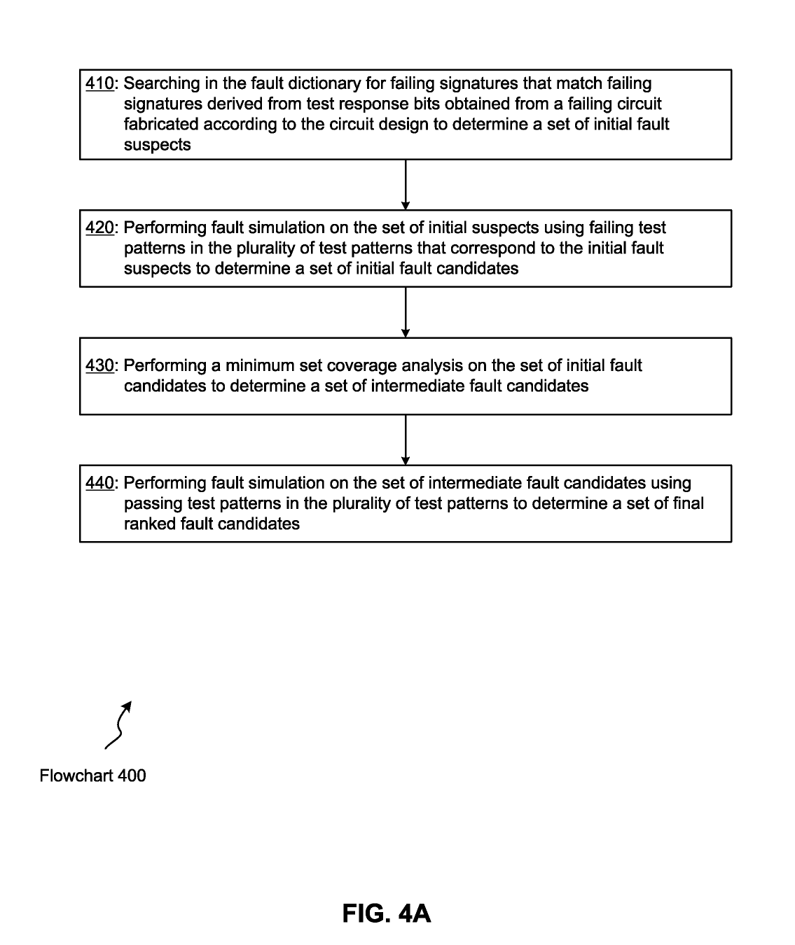

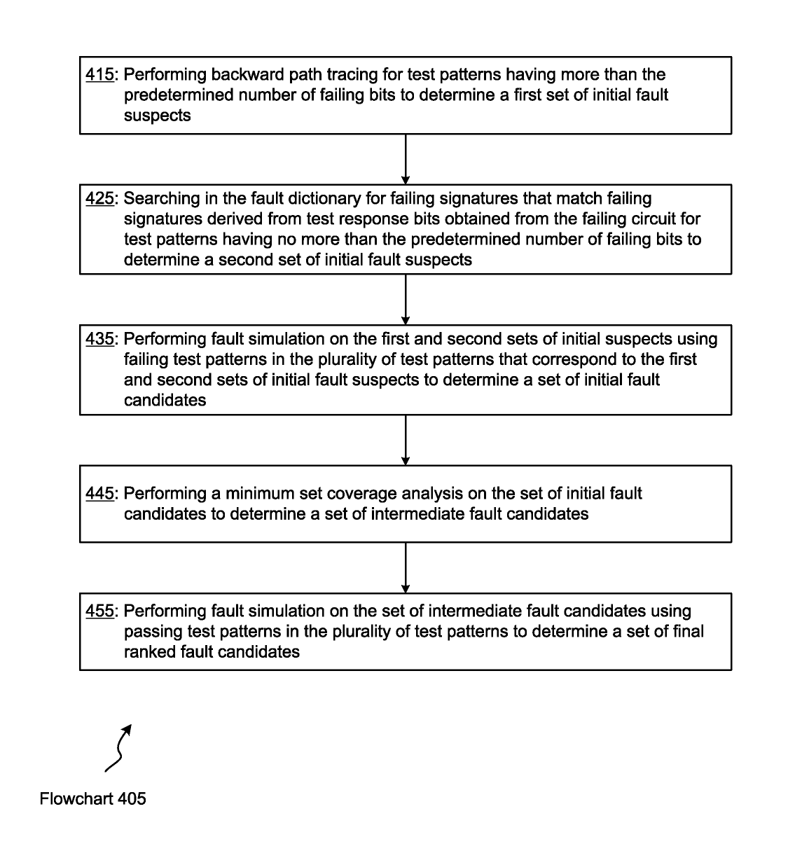

Optionally in operation 350, the effect-cause diagnosis tool 201 performs effect-cause diagnosis based on a set of initial fault suspects. These initial fault suspects are determined using the fault dictionary together with test response bits obtained from a failing circuit fabricated according to the circuit design. Two detailed examples of this process are provided in FIGS. 4A–4B and the corresponding description below.

### Fault Dictionary-Assisted Effect-Cause Diagnosis

FIGS. 4A-4B illustrate flowcharts 400 and 405 showing two processes of fault dictionary-assisted effect-cause diagnosis that may be implemented independently according to various examples of the disclosed technology. For ease of understanding, methods of fault dictionary-assisted effect-cause diagnosis that may be employed according to various embodiments of the disclosed technology will be described with reference to the effect-cause diagnosis tool 201 in FIG. 2 and the flow chart 400 illustrated in FIG. 4A or the flow chart 405 illustrated in FIG. 4B. It should be appreciated, however, that alternate implementations of an effect-cause diagnosis tool may be used to perform the methods of fault dictionary-assisted effect-cause diagnosis illustrated by the flow chart 400 or the flow chart 405 according to various embodiments of the disclosed technology. Likewise, the effect-cause diagnosis tool 201 may be employed to perform other methods of fault dictionary-assisted effect-cause diagnosis according to various embodiments of the disclosed technology.

In operation 410 of the flow chart 400, the initial suspect determination unit 230 searches in the fault dictionary for failing signatures that match failing signatures derived from test response bits obtained from a failing circuit fabricated according to the circuit design to determine a set of initial fault suspects. The fault dictionary is generated by the fault dictionary generation tool 200 as described previously. The effect-cause diagnosis tool 201 can compute the fault signatures based on the test response bits following the same signature derivation method used by the failing signature computation unit 220. In the example mentioned previously, a 32-bit MISR may be employed to derive 32-bit failing signatures.

The fault dictionary has a tree structure. The initial suspect determination unit 230 can start the searching at the root node of the fault dictionary and collect initial suspects recursively down through child nodes, level by level. The difference in failing bits between a child equivalent fault group and its parent equivalent fault group begins at the partition clock cycle; both the child and its parent have the same failing bits before the partition clock cycle. Each equivalent fault group has a failing signature set that is compiled for test patterns within the range spanning from its partition clock cycle to its last failing clock cycle. Thus, if the failing test pattern to be diagnosed falls outside this range, then this equivalent fault group should be included in the initial suspect if and only if one of its ancestor equivalent fault groups, whose partition clock cycle is associated with (or falls within the clock cycles of) the failing test pattern is included. When the failing signature set for a parent equivalent fault group is checked against the failing signature for a failing test pattern because its partition clock cycle is associated with the failing test pattern, there is no need to check its children or grandchildren for the same failing signature. Therefore, the tree structure of the fault dictionary not only keeps the dictionary compact but also accelerates the diagnosis process. The number of initial suspects is also reduced because the failing signature set is for a certain pattern range only and the chance of matching is reduced.

In operation 420 of the flow chart 400, the fault simulation unit 240 performs fault simulation on the set of initial suspects using failing test patterns in the plurality of test patterns that correspond to the initial fault suspects to determine a set of initial fault candidates. A failing test pattern is said to be explained by a fault if the test response bits obtained with the fault injected are the same as the test response bits observed on the tester when the failing test pattern is applied. Only the faults in the set of initial suspects that can explain the failing test patterns are included in the set of initial fault candidates.

In operation 430 of the flow chart 400, the minimum set coverage analysis unit 250 performs a minimum set coverage analysis on the set of initial fault candidates to determine a set of intermediate fault candidates. The set of intermediate fault candidates is a subset of the set of initial fault candidates that includes the minimum number of fault candidates needed to explain all the failing test patterns.

In operation 440 of the flow chart 400, the fault simulation unit 240 performs fault simulation on the set of intermediate fault candidates using passing test patterns in the plurality of test patterns to determine a set of final ranked fault candidates. A passing test pattern mismatch, also referred to as a passing mismatch, can occur whenever a candidate fault is detected by a passing test pattern. The number of passing mismatches, combined with other information, such as failing test pattern matches, may be used to calculate a score for each fault candidate. The fault candidates may be ranked in a descending order of score.

According to some embodiments of the disclosed technology, the failing signature computation unit 220 may compute the failing signatures only for test patterns having no more than a predetermined number of failing bits. Then the methods of fault dictionary-assisted effect-cause diagnosis illustrated by the flow chart 405 may be employed which provide a flexible tradeoff between memory and performance.

In operation 415 of the flow chart 405, the initial suspect determination unit 230 performs backward path tracing for test patterns having more than the predetermined number of failing bits to determine a first set of initial fault suspects. The backward path tracing is based on test response bits obtained from a failing circuit fabricated according to the circuit design.

In operation 425 of the flow chart 405, the initial suspect determination unit 230 searches in the fault dictionary for failing signatures that match failing signatures derived from test response bits obtained from the failing circuit for test patterns having no more than the predetermined number of failing bits to determine a second set of initial fault suspects.

In operation 435 of the flow chart 405, the fault simulation unit 240 performs fault simulation on the first and second sets of initial suspects using failing test patterns in the plurality of test patterns that correspond to the initial fault suspects to determine a set of initial fault candidates.

It should be noted that the operations 425 and 435 may be performed in different orders or concurrently.

In operation 445 of the flow chart 405, the minimum set coverage analysis unit 250 performs a minimum set coverage analysis on the set of initial fault candidates to determine a set of intermediate fault candidates.

In operation 440 of the flow chart 405, the fault simulation unit 240 performs fault simulation on the set of intermediate fault candidates using passing test patterns in the plurality of test patterns to determine a set of final ranked fault candidates.

### Fault Partition Node System Creation

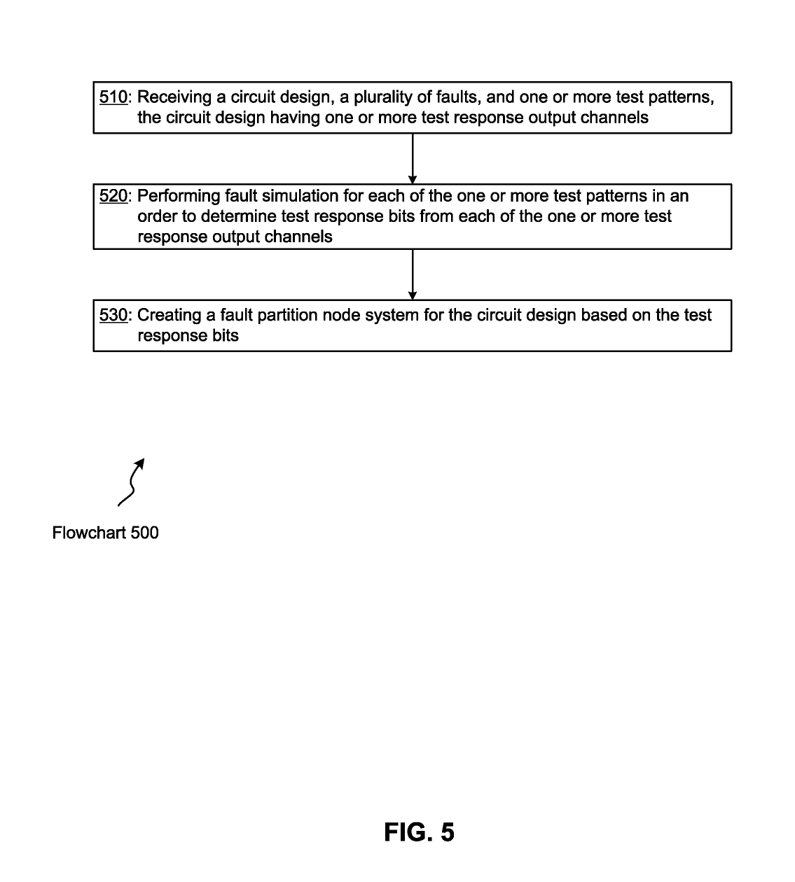

FIG. 5 illustrates a flowchart 500 showing a process of fault partition node system creation that may be implemented according to various examples of the disclosed technology. A fault partition node system can be an observation-clock-cycle-based fault partition node system or a test-pattern-based fault partition node system. The following description will focus on generating an observation-clock-cycle-based fault partition node system. Generating a test-pattern-based fault partition node system can follow a similar process.

In operation 510, a circuit design, a plurality of faults, and one or more test patterns are received. According to some embodiments of the disclosed technology, the plurality of faults may be in a big group or separated into a number of equivalent fault groups. Faults in an equivalent fault group are faults that cannot be distinguished under a certain condition. The certain condition can be test response bits for a group of test patterns which, when used, cannot differentiate one fault in an equivalent fault group from another one in the same equivalent fault group. Equivalent fault groups can be changed with the condition. When additional test response bits for another group of test patterns are employed, some or all of the existing equivalent fault groups can be divided into new equivalent fault groups. The received circuit design has one or more test response output channels. Test response output channels, sometimes referred to as output pins, may be coupled to outputs of scan chains in the circuit design.

In operation 520, fault simulation is performed for each of the one or more test patterns in a sequence to determine a test response bit at each of observation clock cycles from each of the one or more test response output channels. In a typical fault simulation process, a fault is injected into the circuit, and then a test pattern is applied to the fault-injected circuit by launching bits of the test pattern from scan cells to functional circuitry of the circuit. Test response bits generated by the functional circuitry of the circuit are captured by the scan cells and are shifted out either directly from the scan chains or from a compactor after being compacted. The test response bits shifted out of the test response output channels are referred to as observed test response bits, or simply test response bits. The test response bits can comprise passing bits (the same as the corresponding good-machine bits) and failing bits (different from the corresponding good-machine bits). During the shift-out operation, the test response bits come out of each test response output channel one bit per observation clock cycle.

As noted previously, test patterns are shifted into scan chains and applied to the circuit one at a time. After test response bits for the current test pattern are captured, they are being shifted out while the next test pattern is being shifted in. As such, test patterns are applied to the circuit in a particular sequence during scan testing. The sequence in which the one or more test patterns is used for the fault simulation in the operation 520 is the same as the one in which the one or more test patterns would be used to test a circuit fabricated according to the circuit design.

In operation 530, a fault partition node system for the circuit design is created based on the test response bits. The fault partition node system comprises fault partition nodes and equivalent fault groups. Each of the fault partition nodes is associated with one of the equivalent fault groups. Here, the fault partition nodes include a root node. Each of the equivalent fault groups comprises one or more faults in the plurality of faults. When the circuit design has more than one test response output channels, the fault partition node system can be a fault partition node system for the whole circuit design or a fault partition node system for each of the test response output channels. The fault partition node systems generated for individual test response output channels can be combined into the fault partition node system for the whole circuit design.

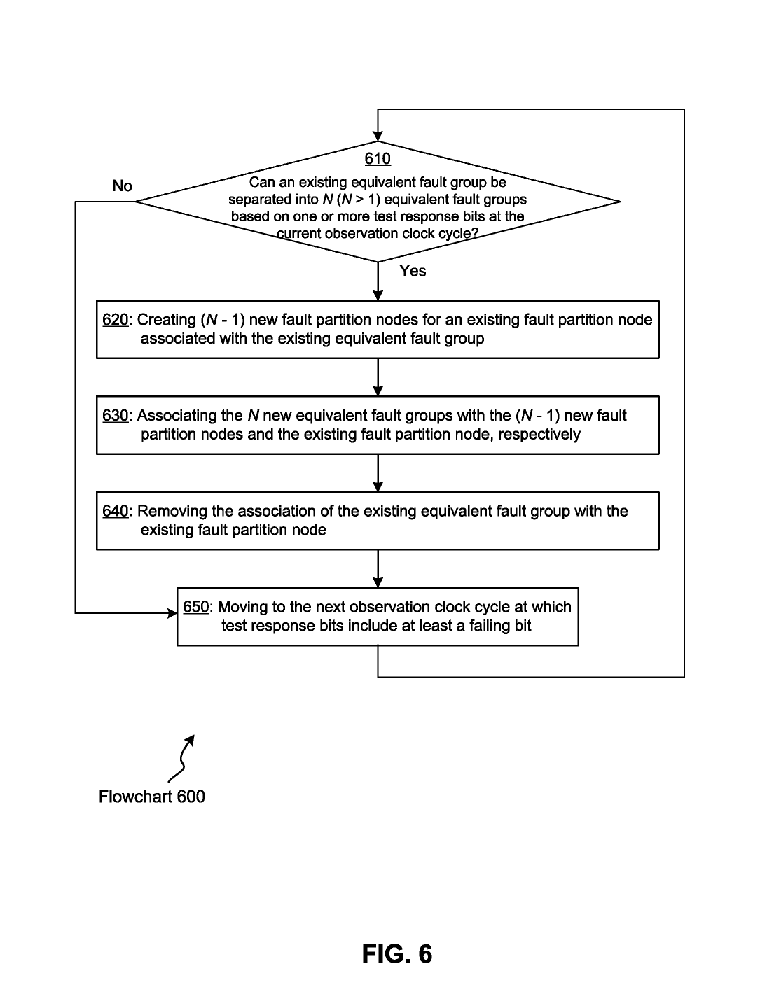

The operation 530 can comprise a series of suboperations for creating new fault partition nodes and for associating new equivalent fault groups with the new fault partition nodes and the existing fault partition nodes. FIG. 6 illustrates a flowchart 600 showing an example process for creating new fault partition nodes that may be implemented according to various examples of the disclosed technology. In operation 610, whether an existing equivalent fault group can be separated into N (N > 1) equivalent fault groups based on one or more test response bits at the current observation clock cycle is determined. If two faults in the existing equivalent fault group have different test response bits, then they can be placed into two new equivalent fault groups. This shows a major difference between fault simulation for test and fault simulation for diagnosis. The former focuses on whether a fault is detectable by comparing test response bits with good-machine test response bits, while the latter focuses on whether faults can be separated by comparing test response bits among themselves (these test response bits may be ones that are derived by comprising with good-machine test response bits). Another difference is about fault list updating. For test purposes, a fault that can be detected by one or more test patterns may be removed from the group of faults and would not be involved in further fault simulation for other test patterns. For diagnosis purposes, on the other hand, a fault that is alone in an equivalent fault group may be removed from the group of faults and would not be involved in further fault simulation for other test patterns. This may be leveraged to speed up the process of fault partition node system generation as will be discussed in more detail below.

If the operation 610 determines that the existing equivalent fault group can be separated into N (N > 1) equivalent fault groups based on the one or more test response bits at the current observation clock cycle, the flow chart 600 will proceed to an operation 620. Otherwise, the flow chart 600 will proceed to an operation 650.

In operation 620, (N – 1) new fault partition nodes are created for an existing fault partition node associated with the existing equivalent fault group. In operation 630, the N new equivalent fault groups are associated with the (N – 1) new fault partition nodes and the existing fault partition node, respectively. According to various embodiments of the disclosed technology, the new equivalent fault group to be associated with the existing fault partition node is the one having the number of failing bits smaller than any of the other new equivalent fault groups. In operation 640, the association of the existing equivalent fault group with the existing fault partition node is removed

In operation 650, which can also be reached directly from the operation 610 as noted previously, the process moves to the next observation clock cycle at which the test response bits include at least a failing bit. The operations 610-650 can be repeated for each of the new equivalent fault groups by treating it as an existing equivalent fault groups unless a new equivalent fault group has only one fault. The reason to skip observation clock cycles at which the test response bits include no failing bit is because that faults cannot be separated based on the test response bits that are all passing bits. The process illustrated by the flow chart 600 may be terminated when the test response bits for all of the test patterns (i.e., for all of the observation clock cycles) are analyzed or each fault in the existing equivalent fault group is placed alone in a new equivalent fault group.

It should be noted that, for each existing equivalent fault group, the process illustrated by the flow chart 600 can be performed independently. Therefore, the process illustrated by the flow chart 600 may be performed for multiple existing fault partition nodes in parallel, which can significantly increase the overall processing speed.

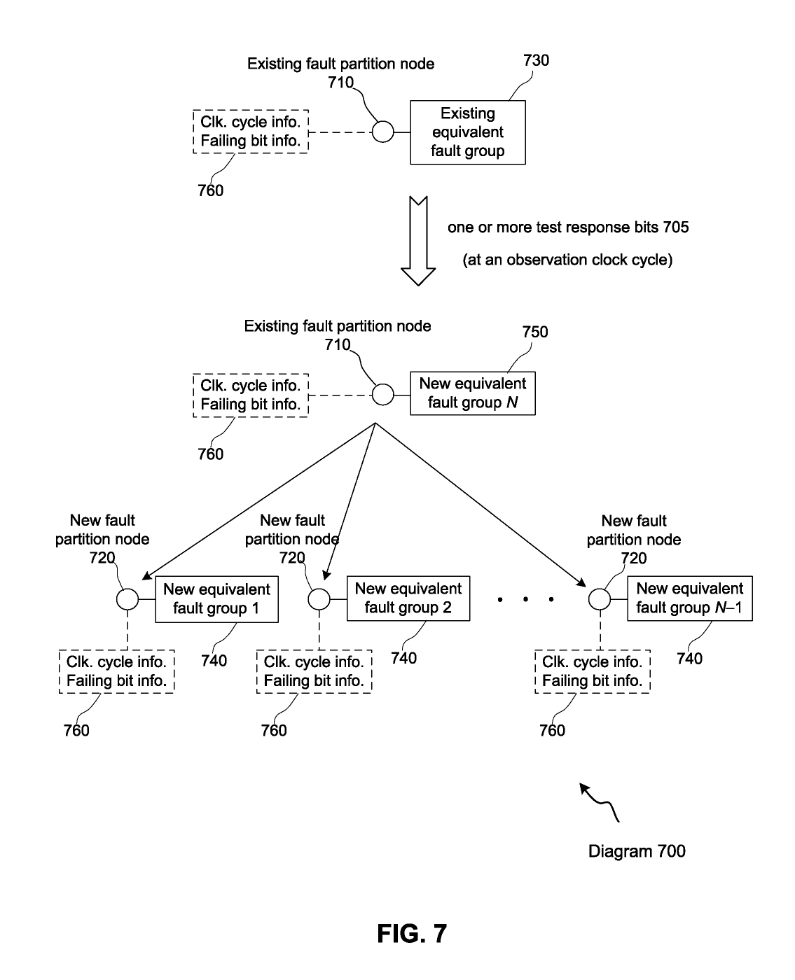

FIG. 7 uses a diagram 700 as an example to illustrate a process for creating new fault partition nodes that may be implemented according to various examples of the disclosed technology. In the diagram 700, an existing fault partition node 710 is initially associated with an equivalent fault group 730. Based on one or more test response bits 705 at an observation clock cycle, the equivalent fault group 730 is divided into (N -1) new equivalent fault groups 740 and a new equivalent fault group 750. Accordingly, (N -1) new fault partition nodes 720 are created. Each of the (N -1) new equivalent fault groups 740 is associated with one of the (N -1) new fault partition nodes 720. The new equivalent fault group 750 is associated with the existing fault partition node 710, replacing the equivalent fault group 730. This can be repeated to further create new fault partition nodes for the newly-created fault partition nodes. According to various embodiments of the disclosed technology, the new equivalent fault group 750 can be the one that has the number of failing bits smaller than any of the new equivalent fault groups 740.

The term “fault partition node system” is a high-level description of a set of related equivalent fault groups derived based on test response bits derived by fault simulation up to a certain observation clock cycle or a test pattern. Accordingly, a process of the fault partition node system generation can be used to derive equivalent fault groups under a particular condition for a particular circuit design. Moreover, a created fault partition node system can show the family relationship between its equivalent fault groups. Some faults are separated from each other at an early stage while others are separated from each other at a late stage. The fault partition node system can also include other information such as the failing bit information, the observation clock cycle information, or both. Combining the family relationship information with the additional information, the fault partition node system can be shrunk or grown further to a new fault partition node system that takes account of some constraint such as the tester storage limit and the number of test patterns applied without redoing the generation process. This is useful for predicting diagnosis coverage values under various constraints.

As noted above, a fault partition node and its associated equivalent fault group may further be associated with failing bit information, observation clock cycle information, or both. FIG. 7 shows failing bit information and observation clock cycle information 760 can be associated with the existing fault partition node 710 and each of the new fault partition nodes 720. Each new equivalent fault group is derived based on a unique combination of failing and passing bits. With this associated failing bit information, the fault partition node system can be used to perform dictionary-based diagnosis. Additionally or alternatively, the failing bit information may include cumulative failing bit counts for a particular fault partition node. This can allow generation of a new fault partition node system for predicting the diagnosis coverage under a constraint associated with a tester. For example, a tester usually only store failing bits and its failing bit buffer has a limited size. To generate a new fault partition node system meeting the constraint, the fault partition nodes having cumulated failing bit counts above a threshold can be merged recursively with corresponding parent fault partition nodes. Using the above process, a profile of diagnosis coverage vs failing bit limit can be derived.

The observation clock cycle information with which the fault partition nodes can be associated shows observation clock cycles at which the fault partition nodes are created. This can allow generation of a new fault partition node system for predicting the diagnosis coverage under a constraint associated with a threshold observation clock cycle or a subgroup of test patterns in the one or more test patterns. To generate the new fault partition node system, the fault partition nodes with which observation clock cycles associated are greater than the threshold observation clock cycle or a largest observation clock cycle for the subgroup of test patterns can be merged recursively with corresponding parent fault partition nodes. Using the above process, a profile of diagnosis coverage vs number of test patterns can be derived.

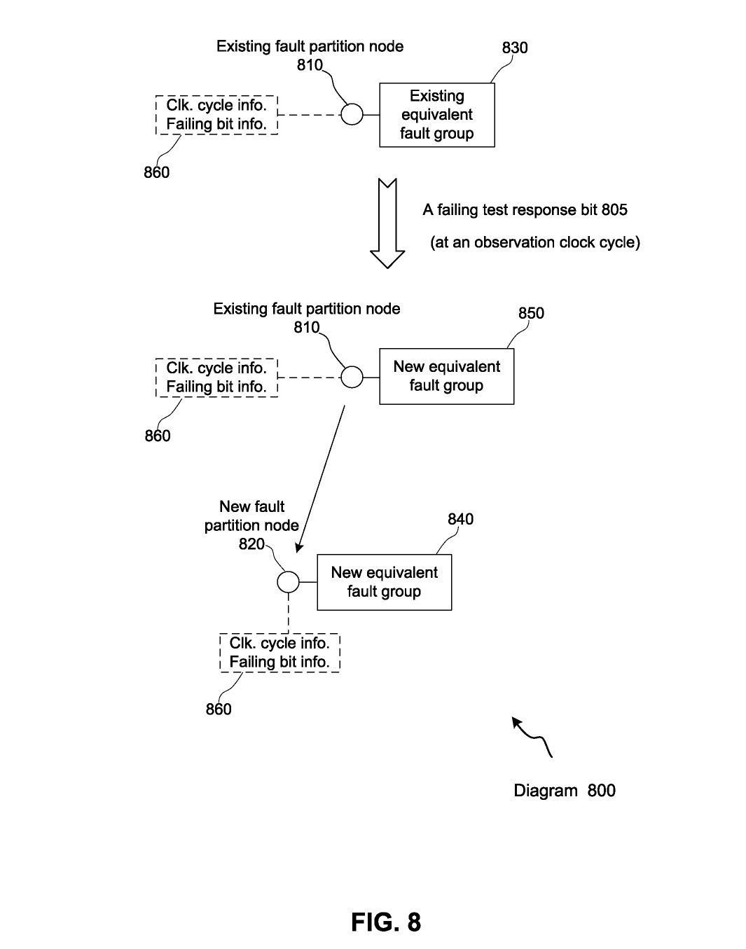

As noted previously, a fault partition node system can be generated for each of the one or more test response output channels. FIG. 8 uses a diagram 800 as an example to illustrate a process for creating new fault partition nodes for one test response output channel that may be implemented according to various examples of the disclosed technology. In the diagram 800, an existing fault partition node 810 is initially associated with an equivalent fault group 830. A single test response output channel can output only one test response bit per observation clock cycle. Only a failing test response bit may separate faults in an existing equivalent fault group into two new equivalent fault groups. In FIG. 8, a single failing test response bit 805 at an observation clock cycle divides the equivalent fault group 830 is divided into two new equivalent fault groups 840 and 850. Accordingly, a new fault partition node 820 is created. The new equivalent fault group 840 is associated with the new fault partition node 820 and the new equivalent fault group 850 is associated with the existing fault partition node 810, replacing the equivalent fault group 830. This can be repeated to further create new fault partition nodes for the newly-created fault partition nodes. In this process, the new equivalent fault group to be associated with the existing fault partition node can be set to be the one that has a passing bit according to some embodiments of the disclosed technology. Under this rule, it is the new equivalent fault group 840 in FIG. 8 that has the failing bit since it is associated with the new fault partition node 820. Similar to FIG. 7, failing bit information and observation clock cycle information 860 can be associated with the existing fault partition node 810 and the new fault partition node 820.

It should be noted that the equivalent fault groups derived for a test response output channel may not be the final equivalent fault groups if the circuit design has more than one test response output channel. The final equivalent fault groups can be obtained by comparing faults in an equivalent fault group in one fault partition node system for one test response output channel with faults in other equivalent fault groups in other fault partition node systems for other test response output channels. This may further separate faults in the equivalent fault groups derived for individual test response output channels.

Referring back to FIG. 5, it should be noted that the operations 520 and 530 do not need to be performed in serial for all of the one or more test patterns. In another word, fault simulation does not need to be performed for all of the one or more test patterns before starting to create the fault partition node system. The two operations may be performed “concurrently.”

A fault partition node system can be an observation-clock-cycle-based fault partition node system or a test-pattern-based fault partition node system. The above description focuses on generating an observation-clock-cycle-based fault partition node system. Generating a test-pattern-based fault partition node system can follow a similar process. Rather than checking whether faults in an equivalent fault group can be distinguished based on test response bits at a particular observation clock cycle, a test-pattern-based fault partition node system generation tool checks whether faults in an equivalent fault group can be distinguished based on test response bits for a test pattern.

### Conclusion

Having illustrated and described the principles of the disclosed technology, it will be apparent to those skilled in the art that the disclosed embodiments can be modified in arrangement and detail without departing from such principles. In view of the many possible embodiments to which the principles of the disclosed technologies can be applied, it should be recognized that the illustrated embodiments are only preferred examples of the technologies and should not be taken as limiting the scope of the disclosed technology. Rather, the scope of the disclosed technology is defined by the following claims and their equivalents. We therefore claim as our disclosed technology all that comes within the scope and spirit of these claims.

What is claimed is:

1. A method, performed by at least one processor of a computer, comprising:
receiving a circuit design, a plurality of faults, and a plurality of test patterns;
creating a fault partition node system for the circuit design based on fault simulation of the plurality of faults for each of the plurality of test patterns, each fault partition node being associated with a respective equivalent fault group;
computing, for each equivalent fault group in the fault partition node system, a respective set of failing signatures, each failing signature in the respective set of failing signatures being derived from test response bits of a respective failing test pattern in the plurality of test patterns that fails for the each equivalent fault group, the respective set of failing signatures comprising failing signatures for failing test patterns spanning from a partition clock cycle of a fault partition node associated with the each equivalent fault group to a last failing clock cycle of the each equivalent fault group; and
storing, as a fault dictionary, the sets of failing signatures, the equivalent fault groups, and parent-child relationship information of the equivalent fault groups.

2. The method recited in claim 1, further comprising:
searching in the fault dictionary for failing signatures that match failing signatures derived from test response bits obtained from a failing circuit fabricated according to the circuit design to determine a set of initial fault suspects;
performing fault simulation on the set of initial suspects using failing test patterns in the plurality of test patterns that correspond to the initial fault suspects to determine a set of initial fault candidates;
performing a minimum set coverage analysis on the set of initial fault candidates to determine a set of intermediate fault candidates; and
performing fault simulation on the set of intermediate fault candidates using passing test patterns in the plurality of test patterns to determine a set of final ranked fault candidates.

3. The method recited in claim 1, wherein the failing signatures are computed only for test patterns having no more than a predetermined number of failing bits.

4. The method recited in claim 3, further comprising:
performing backward path tracing for test patterns having more than the predetermined number of failing bits to determine a first set of initial fault suspects, the backward path tracing being based on test response bits obtained from a failing circuit fabricated according to the circuit design;
searching in the fault dictionary for failing signatures that match failing signatures derived from test response bits obtained from the failing circuit for test patterns having no more than the predetermined number of failing bits to determine a second set of initial fault suspects;
performing fault simulation on the first and second sets of initial suspects using failing test patterns in the plurality of test patterns that correspond to the first and second sets of initial fault suspects to determine a set of initial fault candidates;
performing a minimum set coverage analysis on the set of initial fault candidates to determine a set of intermediate fault candidates; and
performing fault simulation on the set of intermediate fault candidates using passing test patterns in the plurality of test patterns to determine a set of final ranked fault candidates.

5. The method recited in claim 1, wherein the fault simulation is performed for each of the plurality of test patterns in a sequence to determine test response bits from each of one or more test response output channels of the circuit design, the sequence being the same as a sequence in which the plurality of test patterns would be used to test a circuit fabricated according to the circuit design, the test response bits comprising passing bits and failing bits, and
wherein the creating a fault partition node system is based on the test response bits determined by the fault simulation, the fault partition node system comprising fault partition nodes and equivalent fault groups, each of the fault partition nodes being associated with one of the equivalent fault groups, each of the equivalent fault groups comprising one or more faults in the plurality of faults, the generating comprising:
creating (N- 1) new fault partition nodes for an existing fault partition node if an existing equivalent fault group associated with the existing fault partition node is separated into N new equivalent fault groups based on one or more test response bits at an observation clock cycle,
associating the N new equivalent fault groups with the (N- 1) new fault partition nodes and the existing fault partition node, respectively, and
removing the association of the existing equivalent fault group with the existing fault partition node.

6. The method recited in claim 5, wherein the fault partition node system is created for each of the one or more test response output channels, a number of fault partition node systems generated being equal to a number of the one or more test response output channels, wherein N = 2 and the creating comprising:
creating a new fault partition node for an existing fault partition node if an existing equivalent fault group associated with the existing fault partition node is separated into two new equivalent fault groups based on a failing bit at an observation clock cycle;
associating the two new equivalent fault groups with the new fault partition node and the existing fault partition node, respectively; and
removing the association of existing equivalent fault group with the existing fault partition node.

7. The method recited in claim 6, wherein one of the two new equivalent fault groups having the failing bit is associated with the new fault partition node.

8. One or more computer-readable media storing computer-executable instructions for causing one or more processors to perform a method, the method comprising:
receiving a circuit design, a plurality of faults, and a plurality of test patterns;
creating a fault partition node system for the circuit design based on fault simulation of the plurality of faults for each of the plurality of test patterns, each fault partition node being associated with a respective equivalent fault group;
computing, for each equivalent fault group in the fault partition node system, a respective set of failing signatures, each failing signature in the respective set of failing signatures being derived from test response bits of a respective failing test pattern in the plurality of test patterns that fails for the each equivalent fault group, the respective set of failing signatures comprising failing signatures for failing test patterns spanning from a partition clock cycle of a fault partition node associated with the each equivalent fault group to a last failing clock cycle of the each equivalent fault group; and
storing, as a fault dictionary, the sets of failing signatures, the equivalent fault groups, and parent-child relationship information of the equivalent fault groups.

9. The one or more computer-readable media recited in claim 8, wherein the method further comprises:
searching in the fault dictionary for failing signatures that match failing signatures derived from test response bits obtained from a failing circuit fabricated according to the circuit design to determine a set of initial fault suspects;
performing fault simulation on the set of initial suspects using failing test patterns in the plurality of test patterns that correspond to the initial fault suspects to determine a set of initial fault candidates;
performing a minimum set coverage analysis on the set of initial fault candidates to determine a set of intermediate fault candidates; and
performing fault simulation on the set of intermediate fault candidates using passing test patterns in the plurality of test patterns to determine a set of final ranked fault candidates.

10. The one or more computer-readable media recited in claim 8, wherein the failing signatures are computed only for test patterns having no more than a predetermined number of failing bits.

11. The one or more computer-readable media recited in claim 10, wherein the method further comprises:
performing backward path tracing for test patterns having more than the predetermined number of failing bits to determine a first set of initial fault suspects, the backward path tracing being based on test response bits obtained from a failing circuit fabricated according to the circuit design;
searching in the fault dictionary for failing signatures that match failing signatures derived from test response bits obtained from the failing circuit for test patterns having no more than the predetermined number of failing bits to determine a second set of initial fault suspects;
performing fault simulation on the first and second sets of initial suspects using failing test patterns in the plurality of test patterns that correspond to the first and second sets of initial fault suspects to determine a set of initial fault candidates;
performing a minimum set coverage analysis on the set of initial fault candidates to determine a set of intermediate fault candidates; and
performing fault simulation on the set of intermediate fault candidates using passing test patterns in the plurality of test patterns to determine a set of final ranked fault candidates.

12. The one or more computer-readable media recited in claim 8, wherein the fault simulation is performed for each of the plurality of test patterns in a sequence to determine test response bits from each of one or more test response output channels of the circuit design, the sequence being the same as a sequence in which the plurality of test patterns would be used to test a circuit fabricated according to the circuit design, the test response bits comprising passing bits and failing bits, and
wherein the creating a fault partition node system and the expanding the fault partition node system are based on the test response bits determined by the fault simulation, the fault partition node system comprising fault partition nodes and equivalent fault groups, each of the fault partition nodes being associated with one of the equivalent fault groups, each of the equivalent fault groups comprising one or more faults in the plurality of faults, the generating comprising:
creating (N-1) new fault partition nodes for an existing fault partition node if an existing equivalent fault group associated with the existing fault partition node is separated into N new equivalent fault groups based on one or more test response bits at an observation clock cycle,
associating the N new equivalent fault groups with the (N-1) new fault partition nodes and the existing fault partition node, respectively, and
removing the association of the existing equivalent fault group with the existing fault partition node.

13. The one or more computer-readable media recited in claim 10, wherein the fault partition node system is created for each of the one or more test response output channels, a number of fault partition node systems generated being equal to a number of the one or more test response output channels, wherein N = 2 and the creating comprising:
creating a new fault partition node for an existing fault partition node if an existing equivalent fault group associated with the existing fault partition node is separated into two new equivalent fault groups based on a failing bit at an observation clock cycle;
associating the two new equivalent fault groups with the new fault partition node and the existing fault partition node, respectively; and
removing the association of existing equivalent fault group with the existing fault partition node.

14. The one or more computer-readable media recited in claim 13, wherein one of the two new equivalent fault groups having the failing bit is associated with the new fault partition node.
